(19) United States
(12) Patent Application Publication
(10) Pub. No.: US 2003/0186074 A1
(43) Pub. Date: Oct. 2, 2003

(54) Metal electrode using molybdenum-tungsten alloy as barrier layers and the fabrication method of the same

(76) Inventors: Chi-Lin Chen, Hsinchu City (TW); Chich-Shang Chang, Hsinchu City (TW)

Correspondence Address: BIRCH STEWART KOLASCH & BIRCH, PO BOX 747, FALLS CHURCH, VA, 22040-0747, US

(21) Appl. No.: 10/112,708

(22) Filed: Apr. 2, 2002

(51) Int. Cl. B32B 15/00; C25D 1/00; B32B 15/10; H01L 21/44

(52) U.S. Cl. 428/651; 428/663; 428/665; 438/653; 438/685

(57) ABSTRACT

This specification discloses a metal electrode that uses MoW (molybdenum-tungsten) alloy as its barrier layers and the method for making the same. Using MoW alloy as the barrier layer of a metal electrode can effectively solve the spiking and hillock problems occurred in aluminum electrodes. The MoW alloy barrier layer is thermally stable, preventing the resistance from rising due to the high-temperature manufacturing process. The metal electrode using the MoW alloy as the barrier layer can be prepared using the dry etching process. The resulting resistance is lower than other kinds of barrier layers. The MoW alloy barrier layer can be used in TFT metal electrodes for high-resolution and large-area displays.

### BACKGROUND OF THE INVENTION

1. Field of Invention

The invention relates to a metal electrode using MoW alloy as its barrier layers and the method for making the same. More particularly, the invention relates to a dry etching prepared metal electrode using MoW alloy as its barrier layers and the method for making the same.

2. Related Art

The thin film transistor (TFT) as become an important component in active displays. As displays have higher resolution and larger areas, it is also necessary for its metal electrode and signal circuit to have low resistance to reduce electric signal delays. Since aluminum and aluminum alloys have relatively low resistance (about 2 μΩ-cm) and it has such good properties as mature technology, easy etching and strong binding with other materials, they are often selected as the primary materials for the signal lines and electrodes. However, silicon and aluminum can form a homogeneous admixture and the silicon atoms can rapidly diffuse in the aluminum thin film, resulting hole formation at the Al—Si interface. This in turn causes the serious penetration problem of aluminum in the silicon semiconductor, i.e. the aluminum spiking problem. In addition, the connecting line thickness and width among the components decreases with the device size when using aluminum as the connection. The density of the current flowing through the wires thus increases, resulting in the electromigration problem. Since the electromigration results from interactions among conducting electrons and metal atoms, the metal atoms will move along the crystal boundary and form a hillock along the connections among the components but voids on the other end.

To avoid the device failure caused by the hillock and spiking problems on the aluminum electrodes, a commonly used method employed in the prior art is to sputter a barrier layer on the top and bottom surfaces of the aluminum electrodes, forming a three-layer structure. Normally, Ti or Cr are used as the barrier layer materials. However, titanium is likely to form TiAl₃ alloy with the aluminum during high-temperature processes, resulting in higher resistance. This is harmful for subsequent thermal processing. Chromium, on the other hand, has the problems of low etching yield and environmental pollution. In the U.S. Pat. No. 6,081,308, it was proposed to form a two-layer metal electrode by using Mo or MoW alloy with a low tungsten concentration (0%˜20% in atoms) as the barrier layer sputtered on an aluminum electrode surface. It can be used in a bottom gate structure, preventing the hillock and spiking problems on the metal electrode and other difficulties in titanium and chromium. In the patent, the wet etching is suggested. As the future trend is to use top gates as the primary structure, the two-layer metal electrodes are not sufficient. Furthermore, the wet etching method is an isotropic etching process, which put a constraint on the minimum line width for the wires.

### SUMMARY OF THE INVENTION

It is thus an objective of the invention to solve the problems with aluminum electrode in conventional TFT's. The invention proposes to use MoW alloy as the barrier layer in the metal electrode and a method to prepare the same. Using MoW alloy barrier layer in place of the conventional barrier layers (e.g. Ti or Cr) can avoid the problem of rising resistance during high temperature processes in the Ti barrier layer and those of low etching yield and pollution when using the Cr barrier. The MoW alloy barrier layer has a high thermal stability; its resistance does not increase in the subsequent high temperature processes (400° C. to 500° C.). Moreover, the MoW barrier has extremely good binding with silicon, SiO₂ and ITO glass. In developing large-area and high-resolution displays, scan circuits with lower resistance are often required to eliminate signal delays in large-area displays, while dry etching has to be used for high-resolution displays to make small-width lines. Metal electrodes with MoW alloy as the barrier layers thus have low resistance and allow dry etching to form required circuits, ideal for making large-area and high-resolution displays.

Since the invention uses MoW alloy as the barrier layer material on the metal electrode, electric signal delays can be reduced or eliminated. The MoW alloy barrier layer is formed on electrode layers, other metal layers, or semiconductor layer junction surfaces to protect the electrode layers. It is helpful in preventing the hillock and junction spiking problems at the junction surface. The electrode layer uses either aluminum or aluminum alloy as the electrode material. The MoW barrier layer is formed by sputtering, evaporation or CVD (Chemical Vapor Deposition). The metal electrode of the invention has two different structures: one is a three-layer electrode with barrier layers formed on the top and bottom surfaces of the electrode layer to protect the electrode layer; the other is a two-layer structure with an electrode layer directly formed on the surface of a substrate and a barrier layer formed on the electrode layer surface. The three-layer electrode structure can be applied to TFT metal electrodes and in data lines and scan lines of large-area and high-resolution LCD's. The two-layer electrode structure is mainly used in the bottom gate structure and the metal electrode and wires in direct contact with the substrate. The substrate material is selected from mono-silicon, polysilicon, SiO₂, and ITO (Indium Tin Oxide) conductive glass. The MoW alloy for the surface barrier layer is preferably to have a tungsten concentration between 20% and 99%. The tungsten concentration is preferably to be 50%.

The method of making the metal electrode using the MoW alloy as the barrier layer includes the steps of: forming a photoresist pattern on a metal electrode surface, etching the metal electrode to form a desired metal electrode circuit, removing the photoresist pattern from the metal electrode surface, wherein the etching is plasma etching in the dry etching category.

### BRIEF DESCRIPTION OF THE DRAWINGS

The invention will become more fully understood from the detailed description given hereinbelow illustration only, and thus are not limitative of the present invention, and wherein:

FIG. 1 is a schematic view of a three-layer metal electrode structure using MoW alloy as its barrier layers;

FIG. 2 is a schematic view of a two-layer metal electrode structure using MoW alloy as its barrier layer; and

FIGS. 3A to 3E show the procedure of making the disclosed metal electrode using the plasma etching process.

### DETAILED DESCRIPTION OF THE INVENTION

According to the invention, there are two different types of metal electrodes in structure. One is a three-layer structure and the other is a two-layer structure. The three-layer structure includes an electrode layer 10, a top barrier layer 11, and a bottom barrier layer 12. The top barrier layer 11 and the bottom barrier layer 12 are formed on the top and bottom surfaces of the electrode layer 10 to protect the electrode layer 10. This three-layer electrode structure can be applied to the top gate, data lines and scan lines of a TFT, or even other semiconductor metal electrodes and conducting circuits.

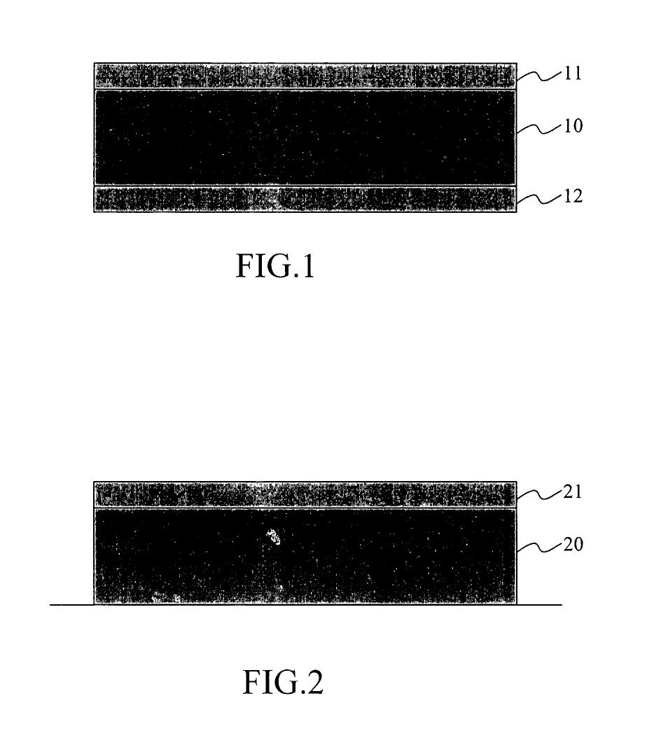

As shown in FIG. 1, the electrode layer 10 of the metal electrode is made of a metal with low resistance to avoid electric signal transmission delay. The top and bottom surfaces of the electrode layer are formed, respectively, with a top barrier layer 11 and a bottom barrier layer 12 that are made of MoW alloy. A three-layer electrode structure is thus formed to protect the electrode layer 10 and to prevent the electrode layer 10 from hillock and junction spiking. The electrode layer 10 can be made of aluminum or aluminum alloys. The top barrier layer 11 and the bottom barrier layer 12 are formed by sputtering, evaporation, or CVD.

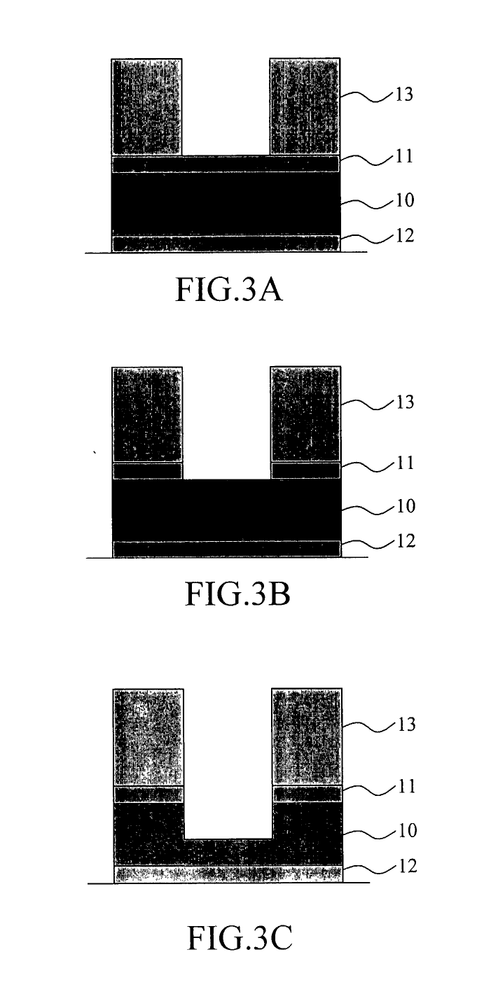

Another embodiment of the invention is shown in FIG. 2. The two-layer electrode structure is applied to the bottom gate of TFT LCD's and the metal electrodes and conductive lines of other semiconductor components. The structure is formed by depositing an electrode layer 20 directly on a substrate surface. A barrier layer is then formed on the electrode layer surface, rendering a two-layer structure. The substrate material is selected from one of mono-silicon, polysilicon, SiO₂, and ITO (Indium Tin Oxide) conductive glass. The electrode layer 20 is made of aluminum or aluminum alloys. The barrier layer 21 and the bottom barrier layer 12 are formed by sputtering, evaporation, or CVD. The MoW alloy for the barrier layer 21 is preferably to have a tungsten concentration between 20% and 99%. According to a preferred embodiment of the invention, the tungsten concentration is 50%.

To make the above-mentioned three-layer or two-layer metal electrode structures using MoW alloy as its barrier layers, an appropriate procedure has to be used. Since wet etching is an anisotropic etching, the width of a narrow line may be too small after etching. Therefore, the minimum width thus made has a lower limit. Since high-resolution, large area TFT LCD's require finer conductive wires, the dry etching thus becomes the primary choice. Both three-layer and two-layer structures can be manufactured using the method described below.

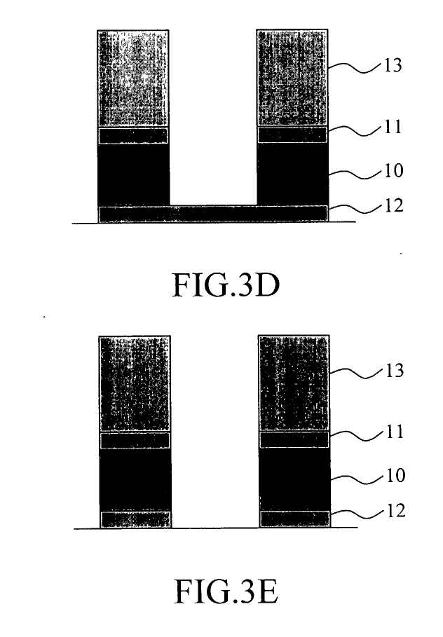

According to the invention, the manufacturing steps are as follows. First, a photoresist pattern is formed on a metal electrode surface with MoW alloy as its barrier layers. The photoresist on the metal electrode is then removed by etching to provide a desired metal electrode circuit. The photoresist removal is achieved by a dry etching method. For the three-layer structure, the plasma etching is employed in an embodiment, as shown in FIGS. 3A through 3E. Regarding the choice of plasma, both chloride and fluoride based plasmas can be used to etch the MoW alloy layer. However, the fluoride based plasma and the aluminum in the electrode layer 10 will coalesce to form residual AlF₃. Since the etching rate of each portion in the MoW alloy layer is not the same, the chloride based plasma has to be used for etching the top barrier layer 11 first to avoid the combination of aluminum 10 and the fluoride ion (FIG. 3A). Afterwards, plasma with a mixture of Cl₂ and BCl₃ is used to etch the aluminum electrode layer 10 (FIG. 3B). As a rising etching temperature is likely to deteriorate the photoresist 13, resulting in remains when removing the photoresist 13. The step of etching the aluminum electrode layer 10 further includes a cooling step that provides helium to lower the temperature to avoid photoresist deterioration. Afterwards, the aluminum electrode layer 10 etching is performed (FIG. 3C). Once it is done, fluoride based gas (e.g. SF₆ and CF₄) is supplied to replace chloride ions by fluoride ions to prevent chloride ion remains from forming HCl due to the contact with air to corrode the metal electrode. Furthermore, oxygen is supplied to oxidize the electrode layer surface, forming a tight protection layer, and oxygen ashing cleans the surface (FIG. 3D). As the electrode layer 10 has been done with etching, the bottom barrier layer 12 can be etched using either chloride based or fluoride based plasmas. Once this etching is done, fluoride based gas and oxygen are supplied again for ion replacement, and oxygen ashing cleans the surface (FIG. 3E).

Moreover, the invention can be implemented using a dry etching process along with a web etching process. The method starts by using chloride plasma to etch the MoW alloy layer. An aluminum etchant in the prior art is then employed to etch the electrode layer in a wet etching way. Finally, either chloride based or fluoride based plasmas are used to etch the bottom MoW alloy layer. The method described above for the three-layer structure can be applied to the two-layer structure too. In the case of two-layer structures, one only needs to perform the step for removing the MoW alloy layer at the bottom surface of the three-layer structure.

Using the disclosed structure and method, a resistance of merely 3 μΩ-cm can be achieved. In addition, the invention can prevent the hillock and spiking problems. It does not have the problem of rising resistance caused by Ti—Al alloys for metal electrodes using Ti as its barrier layers during a high-temperature process. The disclosed electrode using MoW alloy as its barrier layers is processed at a temperature between 400° C. to 500° C.; the resistance is kept essentially unchanged. Therefore, the invention can be used in the metal wires in TFT's that are needed to be processed under high temperature. Since the etching process employed in the disclosed method is dry etching, the line width is not constrained and thus the electrode and circuit density can be increased, which is ideal for high-resolution and large-area TFT LCD's.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A metal electrode using MoW alloy as its barrier layers, which comprises:
an electrode layer, which is made of a metal electrode material of low resistance;
a top barrier layer, which is made of the MoW alloy and formed on the top surface of the electrode layer; and
a bottom barrier layer, which is made of the MoW alloy and formed on the bottom surface of the electrode layer.

2. The metal electrode of claim 1, wherein the metal electrode material is selected from the group consisting of aluminum and aluminum alloys.

3. The metal electrode of claim 1, wherein the top barrier layer and the bottom barrier layer are formed using a means selected from the group consisting of sputtering, evaporation and CVD (Chemical Vapor Deposition).

4. A method for preparing a three-layer metal electrode with a top barrier layer, an electrode layer, and a bottom barrier layer with the barrier layers made of MoW alloy, which method comprises the steps of:
forming a desired photoresist pattern on the metal electrode surface;
using a chloride based plasma to etch the top barrier layer;
etching the electrode layer;
using plasma to etch the bottom barrier layer; and
removing the photoresist pattern from the metal electrode surface to provide the desired metal electrode circuit.

5. The method of claim 4, wherein the step of etching the electrode layer uses a method selected from the group consisting of dry etching and wet etching.

6. The method of claim 5, wherein the dry etching uses a chloride based plasma with a mixture of Cl₂ and BCl₃.

7. The method of claim 6, wherein the step of using the chloride based plasma to etch the electrode layer is followed by a step of protecting the electrode layer, in which SF₆ and oxygen are supplied to replace chloride ions by fluoride ions and to oxidize the electrode layer surface for producing a protection layer.

8. The method of claim 6, wherein the dry etching method includes a cooling step of providing helium to lower the etching temperature, preventing the photoresist in the photoresist pattern from deteriorating.

9. The method of claim 4, wherein the step of using plasma to etch the bottom barrier layer uses plasma selected from the group consisting of chloride based plasma and fluoride based plasma.

10. The method of claim 9, wherein the step of using chloride based plasma to etch the bottom barrier layer is followed by a step of protecting the electrode layer, in which SF₆ and oxygen are supplied to replace chloride ions by fluoride ions and to oxidize the electrode layer surface for producing a protection layer.

11. A metal electrode using MoW alloy as its barrier layers, which comprises:
an electrode layer, which is made of a metal electrode material of low resistance; and
a surface barrier layer, which is made of the MoW alloy with a tungsten concentration ranging from 20% to 99% and formed on a surface of the electrode layer.

12. The metal electrode of claim 11, wherein the metal electrode material is selected from the group consisting of aluminum and aluminum alloys.

13. The metal electrode of claim 11, wherein the substrate material is selected from the group consisting of mono-silicon, polysilicon, SiO₂, and ITO (Indium Tin Oxide) conductive glass.

14. The metal electrode of claim 11, wherein the surface barrier layer is formed using a means selected from the group consisting of sputtering, evaporation and CVD (Chemical Vapor Deposition).

15. The electrode layer of claim 11, wherein the tungsten concentration of the MoW alloy is preferably to be 50%.

16. A method for preparing a two-layer metal electrode with a surface barrier layer and an electrode layer with the barrier layer made of MoW alloy, which method comprises the steps of:
forming a desired photoresist pattern on the metal electrode surface;
using a chloride based plasma to etch the surface barrier layer;
etching the electrode layer; and
removing the photoresist pattern from the metal electrode surface to provide the desired metal electrode circuit.

17. The method of claim 16, wherein the step of etching the electrode layer uses a method selected from the group consisting of dry etching and wet etching.

18. The method of claim 17, wherein the dry etching uses a chloride based plasma with a mixture of Cl₂ and BCl₃.

19. The method of claim 18, wherein the step of using the chloride based plasma to etch the electrode layer is followed by a step of protecting the electrode layer, in which SF₆ and oxygen are supplied to replace chloride ions by fluoride ions and to oxidize the electrode layer surface for producing a protection layer.

20. The method of claim 16, wherein the dry etching method includes a cooling step of providing helium to lower the etching temperature, preventing the photoresist in the photoresist pattern from deteriorating.
